(19) United States
(12) Patent Application Publication
(10) Pub. No.: US 2012/0056178 A1
(43) Pub. Date: Mar. 8, 2012

(54) MULTI-CHIP PACKAGES

(75) Inventors: Won-Gil Han, Suwon-si (KR); Seung-Weon Ha, Cheonan-si (KR); Yong-Je Lee, Asan-si (KR); Han-Ki Park, Cheonan-si (KR)

(73) Assignee: SAMSUNG ELECTRONICS CO., LTD., Suwon-si (KR)

(21) Appl. No.: 13/205,916

(22) Filed: Aug. 9, 2011

(30) Foreign Application Priority Data
Sep. 6, 2010 (KR) 10-2010-0086791

(51) Int. Cl. H01L 23/58

(52) U.S. Cl. 257/48; 257/E23.002

(57) ABSTRACT

A multi-chip package may include a package substrate, a plurality of semiconductor chips and conductive connecting members. The semiconductor chips may be sequentially stacked on the package substrate. Each of the semiconductor chips may include a signal pad and a test pad. The conductive wires may be electrically connected between the signal pad of an upper semiconductor chip among the semiconductor chips and the package substrate via the test pad of a lower semiconductor chip under the upper semiconductor chip. The test pad may be converted into the dummy pad by cutting a fuse.

### CROSS-REFERENCE TO RELATED APPLICATION

This application claims priority under 35 USC §119 to Korean Patent Application No. 10-2010-0086791, filed on Sep. 6, 2010 in the Korean Intellectual Property Office (KIPO), the entire contents of which is incorporated herein by reference.

### BACKGROUND

1. Field

Example embodiments relate to multi-chip packages and methods of manufacturing the same. More particularly, example embodiments relate to multi-chip packages including a plurality of semiconductor packages sequentially stacked, and methods of manufacturing the multi-chip packages.

2. Description of the Related Art

Generally, a plurality of semiconductor fabrication processes may be performed on a semiconductor substrate to form a plurality of semiconductor chips. In order to mount the semiconductor chips on a printed circuit board (PCB), a packaging process may be performed on the semiconductor chips to form semiconductor packages.

In order to increase a storage capacity of a semiconductor package, a multi-chip package including a plurality of sequentially stacked semiconductor chips may be used. The stacked semiconductor chips may be electrically connected with each other via conductive wires. Further, a multi-chip package may include the stacked semiconductor chips having a stepped structure. Upper edge surfaces of the stepped stacked semiconductor chips may be exposed.

Signal pads and test pads may be arranged on the exposed upper edge surfaces of each of the semiconductor chips. The signal pads may transmit operational signals of the semiconductor chips. Thus, the signal pads may be electrically connected with circuits in the semiconductor chips. The signal pads may be electrically connected to a package substrate via conductive wires. In contrast, the test pads may be used for testing electrical characteristics of the semiconductor chips. The test pads may be electrically connected with the circuits in the semiconductor chips, while the test pads may not be electrically connected with the package substrate.

A length of the conductive wire connected between a signal pad of an uppermost semiconductor chip and the package substrate may become longer proportional to the number of stacked semiconductor packages. The long conductive wires may be pushed to one side by a molding member during a molding process, so that a short between the long conductive wires may be frequently generated. In order to prevent a short between the long conductive wires, a dummy pad may be arranged on a lower semiconductor chip between the uppermost semiconductor chip and the package substrate. The conductive wires may extend from the signal pad of the uppermost semiconductor chip to the package substrate via the dummy pad. Because a middle portion of the long conductive wires may be supported by the dummy pad, the shorting of the long conductive wires due to the molding member may be suppressed.

However, it may be required to secure an additional position on the semiconductor chip where the dummy pad may be formed. This may result in increasing a size of the semiconductor chip, so that the multi-chip package may have a large size.

### SUMMARY

Example embodiments may provide small size multi-chip packages that prevent the occurrence of shorting between conductive wires. Example embodiments may also provide methods of manufacturing multi-chip package multi-chip packages that prevent the occurrence of shorting between conductive wires.

According to some example embodiments, there is provided a multi-chip package. The multi-chip package may include a package substrate, a plurality of semiconductor chips and conductive connecting members. The semiconductor chips may be sequentially stacked on the package substrate. Each of the semiconductor chips may have a signal pad and a test pad. The conductive wires may be electrically connected between the signal pad of an upper semiconductor chip among the semiconductor chips and the package substrate via the test pad of a lower semiconductor chip under the upper semiconductor chip.

According to some example embodiments, the test pad may be electrically isolated from circuits in the semiconductor chips. Alternatively, the test pad may be selectively connected with the circuits in the semiconductor chips through a fuse. The fuse may include an e-fuse. According to some example embodiments, the semiconductor chips may be stacked in a stepped structure to expose upper edge surfaces of the semiconductor chips. The signal pad and the test pad may be arranged on the exposed upper edge surfaces of each of the semiconductor chips.

According to some example embodiments, the conductive connecting members may include conductive wires. According to some example embodiments, the multi-chip package may further include a molding member formed on the package substrate to cover the semiconductor chips. According to some example embodiments, the multi-chip package may further include external terminals mounted on a lower surface of the package substrate.

According to some example embodiments, there is provided a method of manufacturing a multi-chip package. In a method of manufacturing the multi-chip package, semiconductor chips may be tested using test patterns of the semiconductor chips that may be connected with circuits in the semiconductor chips via fuses. The fuses may be cut to electrically isolate the test patterns from the circuits in the semiconductor chips. The semiconductor chips may be stacked in a stepped structure to expose the test pads and signal pads of the semiconductor chips. The signal pad of an upper semiconductor chip among the semiconductor chips may be electrically connected with a package substrate via the test pad of a lower semiconductor chip under the upper semiconductor chip.

According to some example embodiments, the fuse may include an e-fuse. According to some example embodiments, the signal pad of the upper semiconductor chip among the semiconductor chips may be electrically connected with the package substrate via the test pad of a lower semiconductor chip under the upper semiconductor chip using conductive wires. According to some example embodiments, the method may further include forming a molding member on the package substrate to cover the semiconductor chips. According to some example embodiments, the method may further include mounting external terminals on a lower surface of the package substrate.

According to some example embodiments, the test pad may be electrically connected with the circuits in the semiconductor chips via the fuse. Thus, after testing the semiconductor chips, the fuse may be cut to electrically isolate the test pad from the circuits. The signal pad may be electrically connected to the package substrate via the test pad using the conductive wire, so that forming additional dummy pads on the semiconductor chips may not be required. As a result, a size of the multi-chip package may be small.

According to at least one example embodiment, a multi-chip package includes a substrate, a plurality of semiconductor chips stacked on a first surface of the substrate, each of the semiconductor chips including a signal pad and a test pad and a conductive connecting member electrically connected to the signal pad of a first semiconductor chip of the plurality of semiconductor chips, the substrate, and the test pad of a second semiconductor chip of the plurality of semiconductor chips, the second semiconductor chip between the first semiconductor chip and the substrate.

According to at least one other example embodiment, a multi-chip package includes a substrate including a first circuit, and a first semiconductor chip including a first signal pad and a first test pad, the first test pad conductively connected to the first circuit.

According to at least one further example embodiment, a method of manufacturing a multi-chip package includes testing electrical characteristics of a plurality of semiconductor chips including test pads that are connected by fuses to circuits in the semiconductor chips, cutting the fuses to electrically isolate the test pads from the circuits, stacking the semiconductor chips on a first surface of a substrate in a stepped structure to expose signal pads and the test pads of the semiconductor chips, and electrically connecting the signal pad of a first semiconductor chip of the semiconductor chips to the substrate via the test pad of a second semiconductor chip of the semiconductor chips, the second semiconductor chip between the first semiconductor chip and the substrate.

### BRIEF DESCRIPTION OF THE DRAWINGS

Example embodiments will be more clearly understood from the following detailed description taken in conjunction with the accompanying drawings. FIGS. 1-9 represent non-limiting, example embodiments as described herein.

FIG. 1 is a cross-sectional diagram illustrating multi-chip packages in accordance with some example embodiments;

FIG. 2 is a perspective view illustrating semiconductor chips and conductive wires in a multi-chip package of FIG. 1;

FIG. 3 is a cross-sectional block diagram illustrating a semiconductor chip of FIG. 2;

FIG. 4 is a plan diagram illustrating semiconductor chips and conductive wires of FIG. 2; and

FIGS. 5-9 are cross-sectional block diagrams illustrating methods of manufacturing multi-chip packages of FIG. 1.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

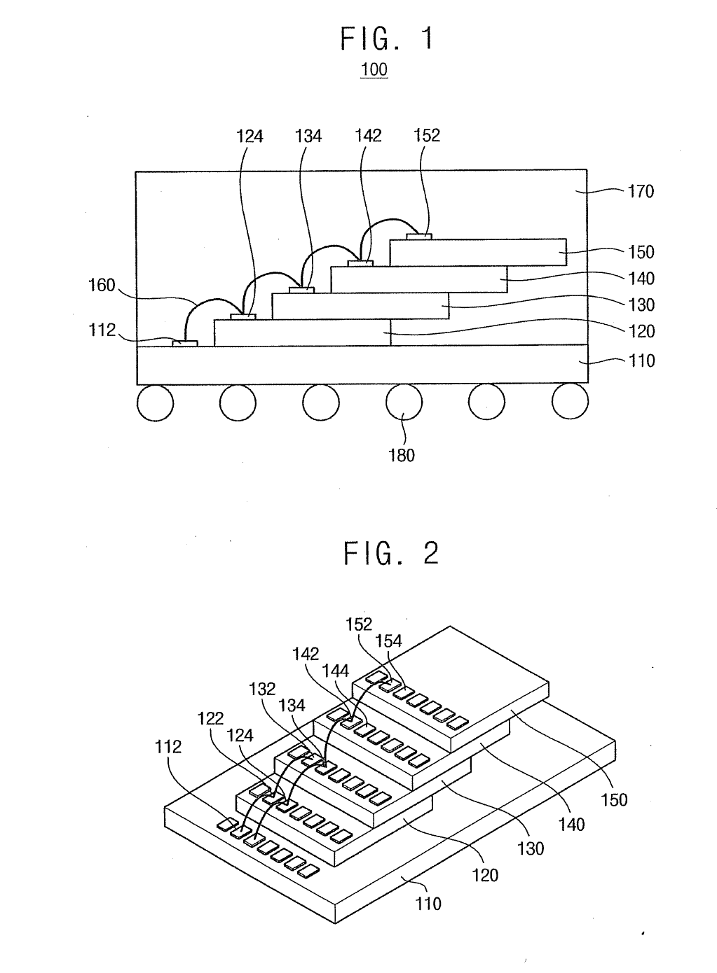

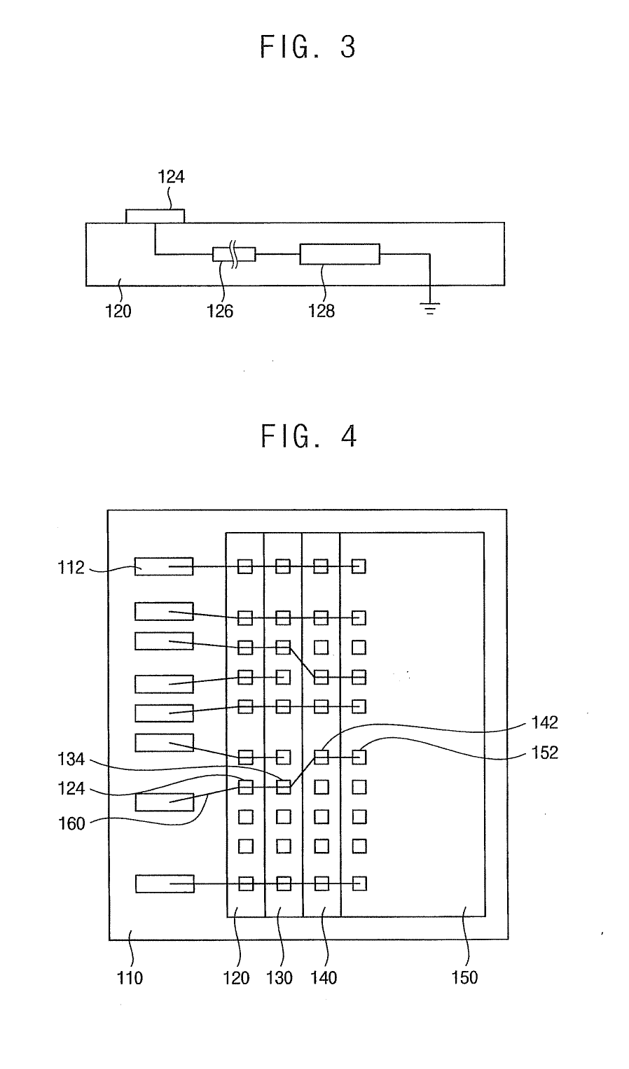

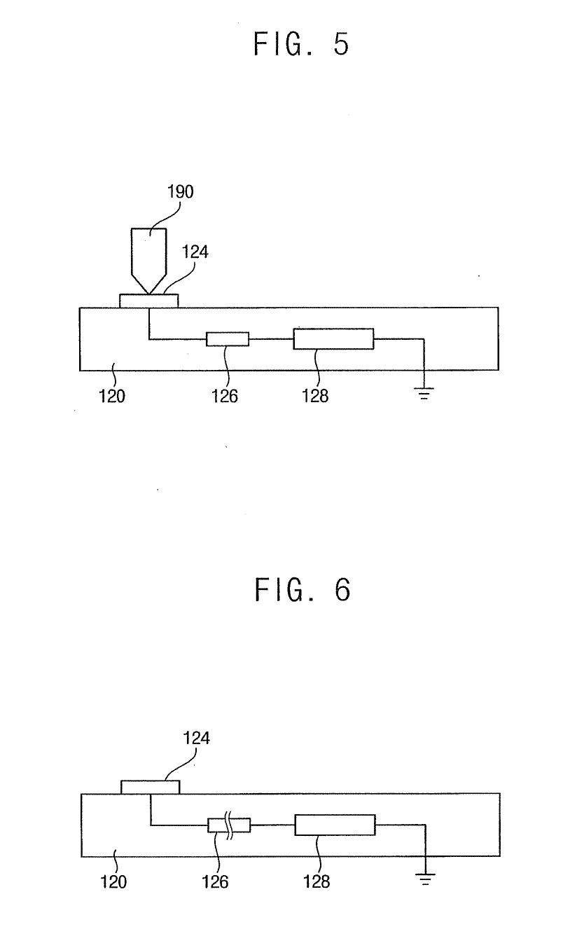

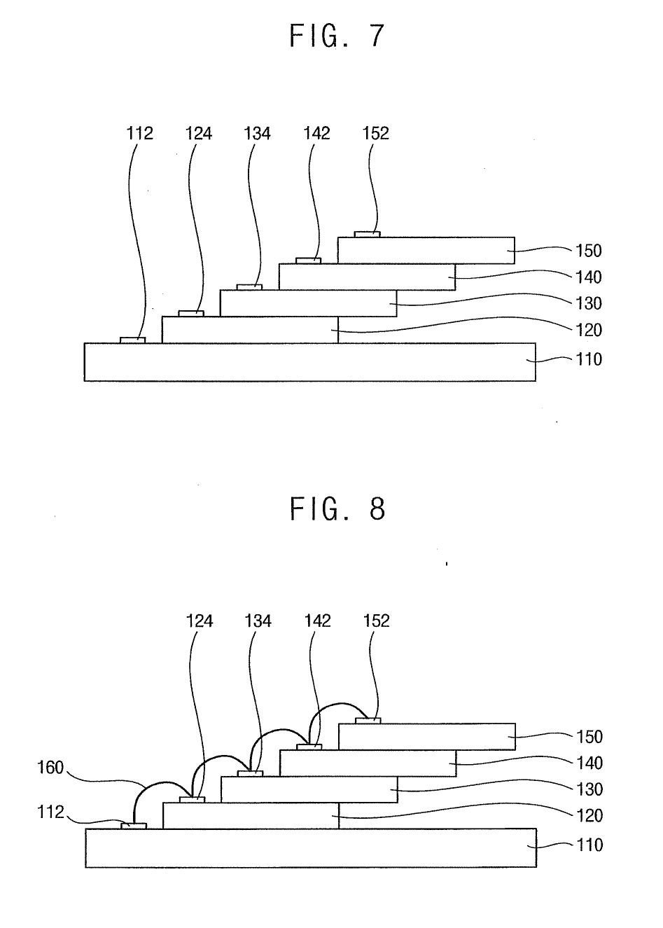

FIG. 1 is a cross-sectional diagram illustrating multi-chip packages in accordance with some example embodiments. FIG. 2 is a perspective view illustrating semiconductor chips and conductive wires in a multi-chip package of FIG. 1. FIG. 3 is a cross-sectional block diagram illustrating a semiconductor chip of FIG. 2. FIG. 4 is a plan diagram illustrating semiconductor chips and conductive wires of FIG. 2. Referring to FIGS. 1-4, a multi-chip package 100 according to example embodiments may include a package substrate 110, a first semiconductor chip 120, a second semiconductor chip 130, a third semiconductor chip 140, a fourth semiconductor chip 150, conductive connecting members 160, a molding member 170 and external terminals 180.

The package substrate 110 may include, for example, an insulating substrate, a circuit pattern formed in the insulating substrate and pads 112 arranged on an upper surface and a lower surface of the insulating substrate. The pads 112 may be electrically connected with the circuit pattern. The first semiconductor chip 120 may be stacked on the package substrate 110. The second semiconductor chip 130 may be stacked on the first semiconductor chip 120. The third semiconductor chip 140 may be stacked on the second semiconductor chip 130. The fourth semiconductor chip 150 may be stacked on the third semiconductor chip 140. The first semiconductor chip 120 may include first signal pads 122 and first test pads 124. The second semiconductor chip 130 may include second signal pads 132 and second test pads 134. The third semiconductor chip 140 may include third signal pads 142 and third test pads 144. The fourth semiconductor chip 150 may include fourth signal pads 152 and fourth test pads 154.

According to some example embodiments, the first signal pads 122 and the first test pads 124 may be arranged on an upper edge surface of the first semiconductor chip 120. The second signal pads 132 and the second test pads 134 may be arranged on an upper edge surface of the second semiconductor chip 130. The third signal pads 142 and the third test pads 144 may be arranged on an upper edge surface of the third semiconductor chip 140. The fourth signal pads 152 and the fourth test pads 154 may be arranged on an upper edge surface of the fourth semiconductor chip 150.

According to some example embodiments, the first semiconductor chip 120, the second semiconductor chip 130, the third semiconductor chip 140 and the fourth semiconductor chip 150 may be stacked in a stepped structure. The upper edge surfaces of the first semiconductor chip 120, the second semiconductor chip 130, the third semiconductor chip 140 and the fourth semiconductor chip 150 may be exposed. The first signal pads 122, the second signal pads 132, the third signal pads 142 and the fourth signal pads 152 may be exposed. The first test pads 124, the second test pads 134, the third test pads 144 and the fourth test pads 154 may be exposed.

According to some example embodiments, the first semiconductor chip 120 may include a first signal pad 122, a first test pad 124, a fuse 126 and a circuit 128. The first signal pad 122 may be used for driving the first semiconductor chip 120. The first signal pad 122 may include an input pad, an output pad, a chip enable pad and the like. The first signal pad 122 may be electrically connected with the circuit 128. The input pad and the output pad of a single semiconductor chip may be connected with each other via the conductive connecting member 160. The chip enable pads of stacked semiconductor chips may be connected with each other via the conductive connecting member 160. For example, chip enable pads of the third semiconductor chip 140 and the fourth semiconductor chip 150 may be connected with each other. The chip enable pads of the third semiconductor chip 140 and the fourth semiconductor chip 150 may not be connected with chip enable pads of the first semiconductor chip 120 and the second semiconductor chip 130.

The first test pad 124 may be used for testing electrical characteristics of the first semiconductor chip 120. After testing the first semiconductor chip 120, it may not be required to connect the first test pad 124 with the circuit 128. The fuse 126 may be arranged between the first test pad 124 and the circuit 128. After testing the first semiconductor chip 120, the fuse 126 may be cut to electrically isolate the first test pad 124 from the circuit 128. The electrically isolated first test pad 124 may be converted into a dummy pad that is not electrically connected to the circuit 128. The second test pad 134, the third test pad 144 and the fourth test pad 154 may be converted into dummy pads by cutting fuses. According to some example embodiments, the fuse 126 may include an e-fuse. An e-fuse may be cut by supplying a cutting current to the e-fuse over a short period of time.

The first test pad 124, the second test pad 134, the third test pad 144 and the fourth test pad 154 may function as dummy pads for supporting middle portions of the conductive connecting members 160. It may not be required to form additional dummy pads on the semiconductor chips 120, 130, 140 and 150. Because it may not be required to secure spaces of the semiconductor chips 120, 130, 140 and 150 where the dummy pads may be formed, the semiconductor chips 120, 130, 140 and 150 may have a small and/or reduced size, so that a size of the multi-chip package 100 may be small and/or reduced.

According to some example embodiments, the second semiconductor chip 130, structures of the third semiconductor chip 140 and the fourth semiconductor chip 150 may be substantially the same as that of the first semiconductor chip 120. Any further illustrations with respect to the second semiconductor chip 130, the third semiconductor chip 140 and the fourth semiconductor chip 150 may be omitted herein for brevity.

The conductive connecting members 160 may be electrically connected between the first to the fourth signal pads 122, 132, 142 and 152 of the first to the fourth semiconductor chips 120, 130, 140 and 150 and the pads 112 of the package substrate 110. According to some example embodiments, the conductive connecting members 160 may include conductive wires. The conductive wires may include, for example, gold and/or aluminum. Electrical isolation between signal pads of a lower semiconductor chip and an upper semiconductor chip may be required. For example, electrical isolation between the third signal pad 142 of the third semiconductor chip 140 and the circuits 128 of the first semiconductor chip 120 and the second semiconductor chip 130 may be required. The conductive connecting member 160 extending from the third signal pad 142 of the third semiconductor chip 140 may not be connected with the first signal pad 122 of the first semiconductor chip 120 and the second signal pad 132 of the second semiconductor chip 130.

The conductive connecting member 160 extending from the third signal pad 142 of the third semiconductor chip 140 may be directly connected to the pad 112 of the package substrate 110 over the first semiconductor chip 120 and the second semiconductor chip 130. The conductive connecting member 160 may have a long loop structure of which a middle portion may not be supported. The long conductive connecting member 160 may be caused to lean by a molding member 170 during a molding process, so that an electrical short between the leaning conductive connecting member 160 and an adjacent conductive connecting member 160 may be generated.

In order to prevent and/or reduce electrical shorting between the conductive connecting members 160, a conductive connecting member 160 may be indirectly connected to the pad 112 of the package substrate 110 via the test pads 124, 134, 144 and 154. For example, the conductive connecting member 160 extending from the third signal pad 142 of the third semiconductor chip 140 may be connected to the pad 112 of the package substrate 110 via the second test pad 134 of the second semiconductor chip 130 and the first test pad 124 of the first semiconductor chip 120. The second test pad 134 and the first test pad 124 may support the middle portion of the conductive connecting member 160, so that the conductive connecting member 160 does not lean during a molding process. Electrical shorting between the conductive connecting members 160 may be suppressed.

According to some example embodiments, the first test pad 124 and the second test pad 134 may be electrically isolated from the circuits 128 by cutting the fuses 126. The conductive connecting member 160 may not be electrically connected with the circuit 128. The third signal pad 142 of the third semiconductor chip 140 may not be electrically connected with the circuits 128 of the first semiconductor chip 120 and the second semiconductor chip 130.

According to some example embodiments, the multi-chip package 100 may include the four stepped semiconductor chips 120, 130, 140 and 150. The multi-chip package 100 may include various numbers of chips, for example, eight stepped semiconductor chips or sixteen stepped semiconductor chips. The third test pad 144 of the third semiconductor chip 140 and the fourth test pad 154 of the fourth semiconductor chip 150 may function as dummy pads for supporting a middle portion of a conductive connecting member 160 originating from semiconductor chips stacked on the fourth semiconductor chip 150.

The molding member 170 may be on an upper surface of the package substrate 110 to cover the first semiconductor chip 120, the second semiconductor chip 130, the third semiconductor chip 140, the fourth semiconductor chip 150 and the conductive connecting members 160. The molding member 170 may protect the first semiconductor chip 120, the second semiconductor chip 130, the third semiconductor chip 140, the fourth semiconductor chip 150 and the conductive connecting members 160 from external environments. According to some example embodiments, the molding member 170 may include, for example, an epoxy molding compound (EMC). External terminals 180 may be mounted on pads 112 on a lower surface of the package substrate 110 (not shown). According to some example embodiments, the external terminals 180 may include, for example, solder balls.

According to at least one example embodiment, a test pad may be converted into the dummy pad by cutting a fuse. The test pad may support (e.g., firmly support) the middle portion of the conductive connecting member. The conductive connecting member may not be caused to lean during the molding process and a space of the semiconductor chip where an additional dummy pad may be formed may not be required. Sizes of the semiconductor chip and the multi-chip package may be small and/or reduced.

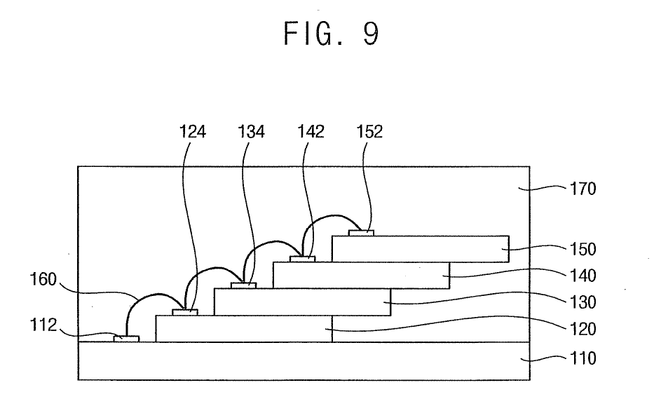

FIGS. 5-9 are cross-sectional block diagrams illustrating methods of manufacturing multi-chip packages of FIG. 1. Referring to FIG. 5, a probe 190 may make contact with the first test pad 124 of the first semiconductor chip 120. A test current may be supplied to the circuit 128 through the probe 190 and the first test pad 124 to test electrical characteristics of the first semiconductor chip 120. An electrical test may be performed on the second semiconductor chip 130, the third semiconductor chip 140 and the fourth semiconductor chip 150.

Referring to FIG. 6, after testing one or more of the first semiconductor chip 120, the second semiconductor chip 130, the third semiconductor chip 140 and the fourth semiconductor chip 150, the fuses 126 may be cut to electrically isolate one or more of the first test pads 124, the second test pads 134, the third test pads 144 and the fourth test pads 154 from the circuits 128. According to some example embodiments, when the fuses 126 include e-fuses, a cutting current may be supplied to the e-fuses over a short time period to cut the e-fuses.

Referring to FIG. 7, the first semiconductor chip 120, the second semiconductor chip 130, the third semiconductor chip 140 and the fourth semiconductor chip 150 may be sequentially stacked on the upper surface of the package substrate 110 in a stepped structure. According to some example embodiments, the upper edge surfaces of the first semiconductor chip 120, the second semiconductor chip 130, the third semiconductor chip 140 and the fourth semiconductor chip 150 may be exposed. The first to the fourth signal pads 122, 132, 142 and 152, and the first to the fourth test pads 124, 134, 144 and 154 may be exposed.

Referring to FIG. 8, the conductive connecting members 160 may be selectively connected between the first to the fourth signal pads 122, 132, 142 and 152 and the first and the fourth test pads 124, 134, 144 and 154. According to some example embodiments, the first signal pad 122 may be connected with the pad 112 of the package substrate 110 using a conductive connecting member 160. The second signal pad 132 may be connected with the pad 112 of the package substrate 110 via the first test pad 124 using the conductive connecting member 160. When the second signal pad 132 includes an input pad or an output pad, the second signal pad 132 may be connected to the pad 112 of the package substrate 110 via an input pad or an output pad among the first signal pads 122.

According to some example embodiments, the third signal pad 142 may be connected with the pad 112 of the package substrate 110 via the second test pad 134 and the first test pad 124 using the conductive connecting member 160. When the third signal pad 142 may include an input pad or an output pad, the third signal pad 142 may be connected the pad 112 of the package substrate 110 via an input pad or an output pad among the first signal pads 122 and the second signal pads 132.

According to some example embodiments, the fourth signal pad 152 may be connected with a pad 112 of the package substrate 110 via the third test pad 144, the second test pad 134 and the first test pad 124 using the conductive connecting member 160. When the fourth signal pad 152 may include a chip enable pad, the fourth signal pad 152 may be connected to the pad 112 of the package substrate 110 via a chip enable pad among the third signal pads 142, a second test pad 134 and the first test pad 124. When the fourth signal pad 152 may include an input pad or an output pad, the fourth signal pad 152 may be connected to the pad 112 of the package substrate 110 via an input pad or an output pad among the first signal pads 122, the second signal pads 132 and the third signal pads 142. Although some connection configurations are described, with specificity one of ordinary skill in the art will understand that various other connection schemes are possible according to example embodiments.

The test pads may firmly support the middle portion of the conductive connecting member 160. The conductive connecting member 160 may not be caused to lean by the molding member 170 during a molding process.

Referring to FIG. 9, the package substrate 110 may be arranged in a cavity of a mold die. A molding compound may be injected into the cavity to form the molding member 170 on the package substrate 110. The molding member 170 may be configured to cover the semiconductor chips 120, 130, 140 and 150 and the conductive connecting members 170. According to some example embodiments, the conductive connecting members 160 may be firmly fixed to the test pads 124, 134, 144 and 154. The conductive connecting members 160 may not be caused to lean by the molding compound, so that an electrical short between the adjacent conductive connecting members 160 may be suppressed.

The external terminals 180, for example solder balls, may be mounted on the lower surface of the package substrate 110 to complete a multi-chip package 100. According to some example embodiments, the external terminals 180 may be formed by a reflow process.

According to at least one example embodiment, a test pad may be converted into a dummy pad by cutting a fuse. This test pad may firmly support a middle portion of the conductive connecting member. The conductive connecting member may not be caused to lean during a molding process. A space of the semiconductor chip where an additional dummy pad may be formed may not be required. A size of the semiconductor chip and the multi-chip package may be small and/or reduced.

While example embodiments have been particularly shown and described, it will be understood by one of ordinary skill in the art that variations in form and detail may be made therein without departing from the spirit and scope of the claims.

1. A multi-chip package, comprising:
a substrate;
a plurality of semiconductor chips stacked on a first surface of the substrate, each of the semiconductor chips including a signal pad and a test pad; and
a conductive connecting member electrically connected to the signal pad of a first semiconductor chip of the plurality of semiconductor chips, the substrate, and the test pad of a second semiconductor chip of the plurality of semiconductor chips, the second semiconductor chip between the first semiconductor chip and the substrate.

2. The multi-chip package of claim 1, wherein the test pad of the second semiconductor chip is electrically isolated from a circuit of the second semiconductor chip.

3. The multi-chip package of claim 1, wherein the test pad of the second semiconductor chip is selectively connected to a circuit of the second semiconductor chip through a fuse.

4. The multi-chip package of claim 3, wherein the fuse includes an e-fuse.

5. The multi-chip package of claim 1, wherein the semiconductor chips are stacked in a stepped structure to expose an edge surface of each of the semiconductor chips.

6. The multi-chip package of claim 5, wherein the signal pads and the test pads of the semiconductor chips are arranged on the exposed edge surfaces of the semiconductor chips.

7. The multi-chip package of claim 1, wherein the conductive connecting member includes a plurality of conductive wires.

8. The multi-chip package of claim 1, further comprising:
a molding member on the first surface of the substrate and covering the semiconductor chips.

9. The multi-chip package of claim 1, further comprising:
external terminals on a second surface of the substrate.

10-14. (canceled)

15. A multi-chip package, comprising:
a substrate including a first circuit; and
a first semiconductor chip including a first signal pad and a first test pad, the first test pad conductively connected to the first circuit.

16. The multi-chip package of claim 15, further comprising:
a second semiconductor chip including a second test pad and a second signal pad on the first semiconductor chip, the second signal pad conductively connected to the first test pad.

17. The multi-chip package of claim 16, further comprising:
a third semiconductor chip including a third test pad and a third signal pad, the third semiconductor chip between the substrate and the first and second semiconductor chips, the first test pad conductively connected to the first circuit via the third test pad; and
a fourth semiconductor chip including a fourth signal pad, the first, second, and third semiconductor chips between the fourth semiconductor chip and the substrate, the fourth signal pad conductively connected to the second signal pad,
wherein the substrate includes a second circuit, and
the third signal pad is conductively connected to the second circuit.

18. The multi-chip package of claim 16, wherein the first semiconductor chip includes a second circuit, and
a fuse is connected between the first test pad and the second circuit.

19. The multi-chip package of claim 18, wherein the first test pad includes a probe mark, and
the fuse electrically isolates the first test pad from the second circuit.

20. The multi-chip package of claim 15, wherein the second signal pad is conductively connected to the first test pad by a connecting member that is external to the first and second semiconductor chips.
